(19) United States
(12) Patent Application Publication
(10) Pub. No.: US 2016/0025794 A1
(43) Pub. Date: Jan. 28, 2016

(54) APPARATUS AND METHOD FOR DETECTING LEAKAGE CURRENT

(71) Applicant: Kongju National University Industry-University Cooperation Foundation, Gongju-si (KR)

(72) Inventor: Hyo Sung KIM, Ansan-si (KR)

(21) Appl. No.: 14/809,787

(22) Filed: Jul. 27, 2015

(30) Foreign Application Priority Data
Jul. 28, 2014 (KR) 10-2014-0095886

(51) Int. Cl. G01R 31/02

(52) U.S. Cl. CPC G01R 31/025

(57) ABSTRACT

Provided is an apparatus and method for detecting leakage current in DC applications, capable of separately operating depending on leakage current patterns of a human body and a facility in a TN grounding system. The apparatus for detecting the leakage current is a leakage current detector in a DC distribution system of the TN grounding manner and includes a leakage current detecting unit configured to detect a current flow between a DC power unit and a load to detect whether the leakage current is generated and a level of the leakage current and a leakage current determining unit configured to determine that the cause of the leakage current is either an electric shock to a human or a facility ground fault according to a rate of hourly change in the level of the leakage current detected in the leakage current detecting unit.

### CROSS-REFERENCE TO RELATED APPLICATIONS

This U.S. non-provisional patent application claims priority under 35 U.S.C. §119 of Korean Patent Application No. 10-2014-0095886, filed on Jul. 28, 2014, the entire contents of which are hereby incorporated by reference.

### BACKGROUND OF THE INVENTION

The present invention relates to an apparatus for detecting leakage current, and more particularly, to an apparatus and method for detecting leakage current in DC applications, capable of separately operating depending on leakage current patterns of a human body and a facility in a TN grounding system.

There is rising interest in DC distribution networks due to changes in technical and social environments such as the rapid supply of renewable energy sources, customer demand for highly reliable and highly efficient electrical networks, and surges in digital loads. Accordingly, safety issues regarding DC distribution networks are continuously being raised. In particular, the human body may get shocked, and devices may be damaged, stopped, or may malfunction due to ground faults, short circuits, faulty insulation, lightning, electric arcs, and electric corrosion, which may result in serious problems.

International standard IEC 60364 classifies grounding systems for electric facilities into three categories—TT, TN, and IT. Among these, the TN grounding system refers to a system in which a power line and an exposed conductive part of a facility enclosure are commonly grounded by using a protective conductor. Thus, when an electric leakage accident occurs, for example, when the power line contacts the enclosure or the human body gets shocked, a change in current sum through the entire power line may be detected to immediately report the fault current. Currently, it is possible to detect a leakage current in an AC system by means of a zero-phase current detector. However, a zero-phase current detector may not be used in a DC system. Thus, a new type of leakage current detecting device needs to be developed.

Since existing leakage current detectors cannot distinguish an electric shock accident to the human body from a ground fault accident at a facility, the threshold value of leakage current detectors has to be set at about 30 mA to protect humans or at a higher level of about 100 mA to about 150 mA to protect a facility from misoperations due to various forms of noise. That is, it is impossible to protect humans at a site where the threshold value is set for protecting the facility, and at a site where the threshold value is set for protecting humans, there could be a serious loss of efficiency in electric power management due to misoperations arising from noise.

As a result, electric shock accidents have to be distinguished into two types of accidents—one involving humans and the other involving facilities, and the development is needed of an integrated leakage current detector capable of separately operating to prevent the two types of accidents from occurring for the effective management of electric power and safety.

### SUMMARY OF THE INVENTION

An object of the present invention is to provide an apparatus and method for detecting leakage current capable of detecting the leakage current in a DC distribution system of a TN grounding manner and distinguishing two leakage current from each other according to human body and facility patterns to perform a current tripping operation.

According to an embodiment of the present invention, there is provided an apparatus for detecting leakage current in a DC distribution system of a TN grounding manner, the apparatus including: a leakage current detecting unit configured to detect a current flow between a DC power unit and a load to detect whether the leakage current is generated and a level of the leakage current; and a leakage current determining unit configured to determine that the cause of the leakage current is either an electric shock to a human or a facility ground fault according to a rate of hourly change in the level of the leakage current detected in the leakage current detecting unit.

The leakage current detecting unit may detect a level of the leakage current corresponding to a difference between current flowing in a first conducting line through which current flows from the DC power unit to the load and current flowing in a second conducting line through which current flows from the load to a ground.

The leakage current detecting unit may include a hall effect sensor current transformer (HCT) disposed to surround a conducting line part including the first and second conducting lines to detect a level of a magnetic field corresponding to the sum of level of the magnetic field generated by the current that flows through the first conducting line and level of the magnetic field generated by the current, which flows in a direction opposite to that of the current flowing through the first conducting line, through the second conducting line, thereby outputting a voltage value corresponding to the level of the leakage current.

The leakage current determining unit may detect the rate of hourly change in the level of the leakage current detected by the leakage current detecting unit to determine the cause of the leakage current.

The leakage current determining unit may determine the cause of the leakage current as the electric shock to the human when the rate of hourly change in the level of the leakage current detected by the leakage current detecting unit until the level of the leakage current increases from a time at which the leakage current is generated to a predetermined first level is less than a predetermined reference rate of change.

The leakage current determining unit may output a trip signal for tripping power provided from the DC power unit immediately after determining the cause of the leakage current as the electric shock to the human.

The leakage current determining unit may determine the cause of the leakage current as the facility ground fault when the rate of hourly change in the level of the leakage current detected by the leakage current detecting unit until the level of the leakage current increases from a time at which the leakage current is generated to a predetermined first level is higher than a predetermined reference rate of change.

If the cause of the leakage current is determined as the facility ground fault, the leakage current determining unit may output a trip signal for tripping power provided from the DC power unit when the level of the leakage current detected by the leakage current detecting unit increases to a predetermined second level that is higher than the first level.

According to another embodiment of the present invention, a method for detecting leakage current in DC distribution system of a TN grounding manner includes: a leakage current detecting process for detecting a current flow between a DC power unit and a load to detect whether the leakage current is generated and a level of the leakage current; and a leakage current determining process for determining that the cause of the leakage current is either an electric shock to a human or a facility ground fault according to a rate of hourly change in the level of the leakage current detected in the leakage current detecting process.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a block diagram of a leakage current detecting apparatus according to an embodiment of the present invention;

FIG. 2A is a view illustrating an outer appearance of a hall effect sensor current transformer (HCT) applied as the leakage current detecting unit according to an embodiment of the present invention;

FIG. 2B is a view illustrating an example of a state in which the HCT of FIG. 2A is installed;

FIG. 2C is a view illustrating an output of the HCT of FIG. 2A according to the detected leakage current;

FIG. 3A is a view explaining a leakage current detecting principle to which the HCT of FIG. 2A is applied, in a normal state in which the leakage current does not exist;

FIG. 3B is a view explaining a leakage current detecting principle to which the HCT of FIG. 2A is applied, in a state in which the leakage current is generated;

FIG. 4 is a flowchart showing a method of detecting leakage current according to an embodiment of the present invention;

FIG. 5A is a graph showing characteristics of the leakage current due to an electric shock to a human body;

FIG. 5B is a graph showing characteristics of the leakage current due to a facility ground fault;

FIG. 6 is a graph comparing a leakage current pattern due to the electric shock with a leakage current pattern due to the ground fault;

FIG. 7A is a graph of experimental results showing operation characteristics when a human body receives a shock, in the apparatus and method for detecting a leakage current according to an embodiment of the present invention;

FIG. 7B is a graph of experimental results showing an example of operation characteristics when a facility ground fault occurs, in the apparatus and method for detecting a leakage current according to an embodiment of the present invention; and

FIG. 7C is a graph of experimental results showing another example of operation characteristics when the facility ground fault occurs, in the apparatus and method for detecting a leakage current according to an embodiment of the present invention.

### DETAILED DESCRIPTION OF PREFERRED EMBODIMENTS

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

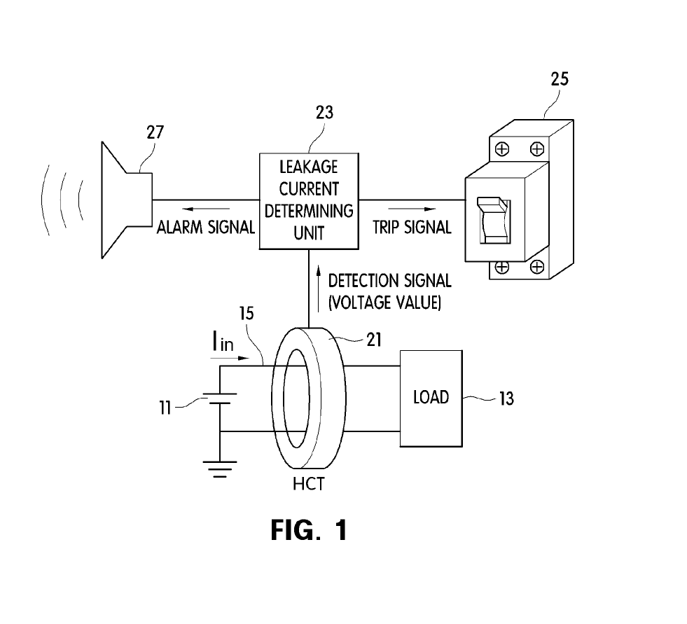

FIG. 1 is a block diagram of a leakage current detecting apparatus according to an embodiment of the present invention.

Referring to FIG. 1, the leakage current detecting apparatus according to an embodiment of the present invention may include a leakage current detecting unit 21 that detects a current flow between a DC power unit 11 and a load 13 to detect whether leakage current is generated and a level of the leakage current and a leakage current determining unit 23 that determines a cause of the leakage current according to a rate of hourly change in the level of the leakage current detected in the leakage current detecting unit 21.

The leakage current detecting unit 21 may detect the current flow between the DC power unit 11 of a DC distribution system according to a TN grounding manner and the load 13 to detect whether the leakage current is generated and the level of the generated leakage current, thereby outputting a detection signal. The leakage current detecting unit 21 may be realized as a Hall effect sensor current transformer (HCT) that detects the level of the DC current.

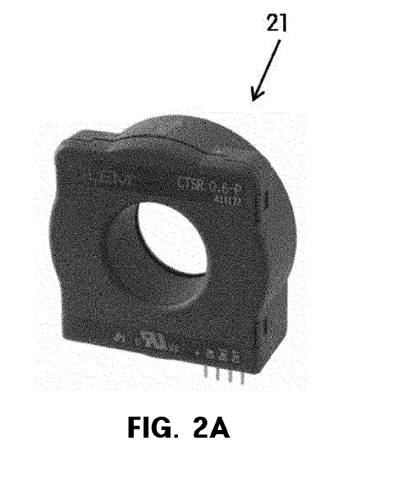

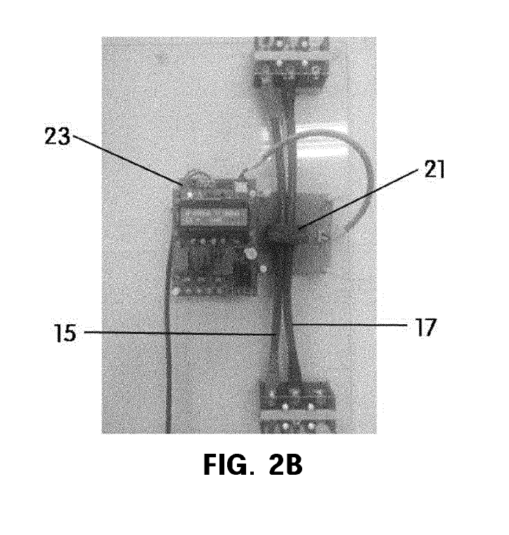

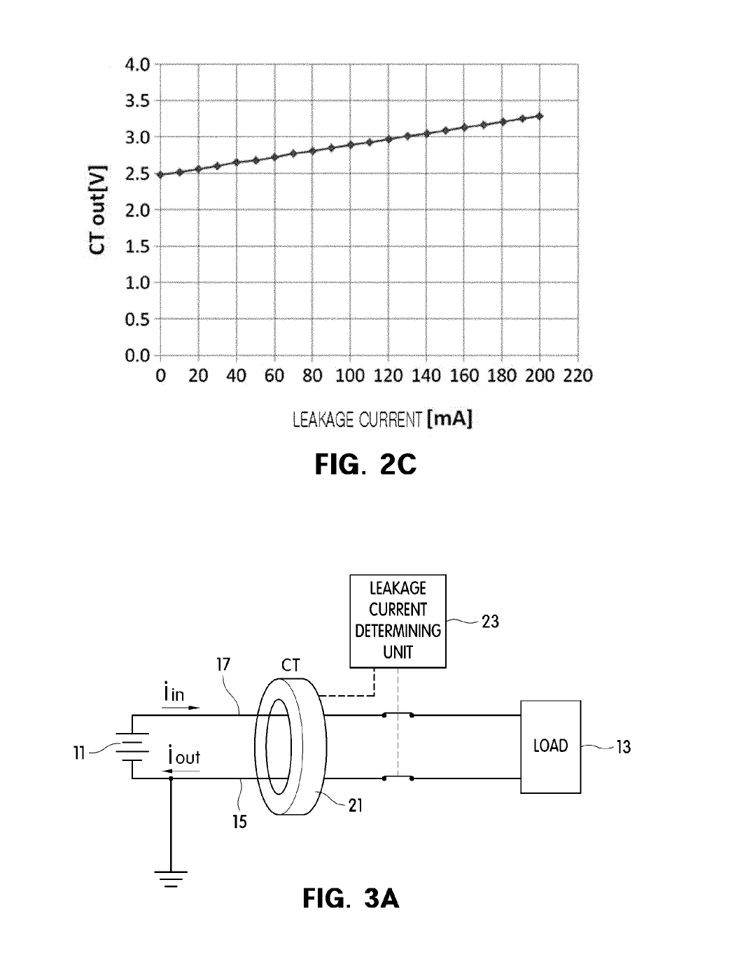

FIG. 2A is a view illustrating an outer appearance of a hall effect sensor current transformer (HCT) applied as the leakage current detecting unit according to an embodiment of the present invention, and FIG. 2B is a view illustrating an example of a state in which the HCT of FIG. 2A is installed, and FIG. 2C is a view illustrating an output of the HCT of FIG. 2A according to the detected leakage current.

As illustrated in FIG. 2A, the HCT 21 includes a magnetic core having a through-hole through which the conducting line passes in a central portion thereof and a hall effect device disposed so that magnetic flux of magnetic fields generated by the current flowing through the conducting line passing through the through-hole passes.

FIG. 2A illustrates a state in which the magnetic core and the hall effect device are covered with an external case. A terminal for providing a predetermined current to the hall effect device and a terminal for receiving a voltage output (the detection signal) generated by the magnetic fields passing through the hall effect device may be disposed outside the case of the HCT 21.

FIG. 2B illustrates an installation state of the HCT 21. The first conducting line 15 through which the current flows from the DC power unit to the load and the second conducting line 17 through which the current flows from the load to the ground may be disposed to pass through the through-hole of the HCT 21, and thus the HCT 21 may be disposed to surround all of the first and second conducting lines 15 and 17 at once. The HCT 21 may detect the level of the magnetic fields corresponding to the sum of the magnetic fields generated by the currents from the first and second conducting lines 15 and 17. The detection signal of the HCT 21 may be provided to the leakage current determining unit 23.

FIG. 2C is a view illustrating an example of the level (the voltage value) of the detection signal outputted from the HCT 21. It can be seen that as the leakage current increases, the level of the detection signal represented as the voltage value of the HCT 21 increases in proportional to the leakage current.

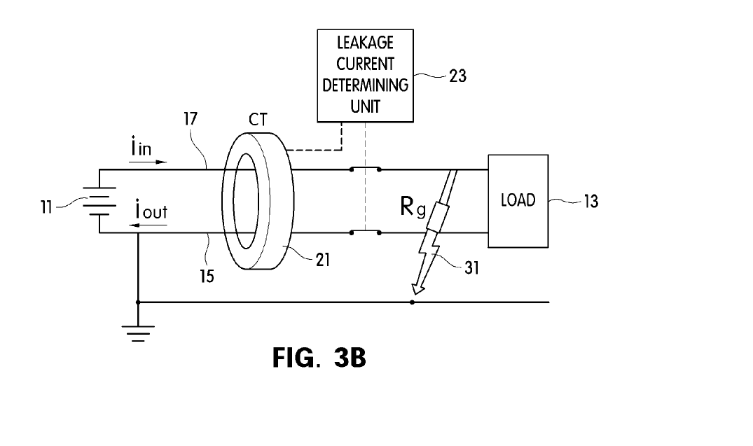

FIG. 3 is a view explaining a leakage current detecting principle to which the HCT of FIG. 2A is applied. As illustrated in FIG. 3A, in a normal state in which the leakage current does not exist, since the currents Iᵢₙ and Iₒᵤₜ flowing through the two conducting lines 15 and 17 passing through the HCT 21 have the same intensity but directions opposite to each other, the sum of the currents is zero. In this case, the hall effect device in the HCT 21 may output a voltage value corresponding to the sum of the magnetic fields generated by the currents flowing through the two conducting lines. In this case, although the level of the voltage value may vary according to a position of the hall effect device in the HCT 21, a level of the detection signal of the HCT 21 in a state in which the leakage current is not generated may be determined as a reference value, and when a detection signal having a value higher than the reference value, it may be determined that the leakage current is generated.

As illustrated in FIG. 3B, in a state in which the leakage current is generated by a cause (for example, the electric shock to human or the ground fault at facility) corresponding to other resistance R_{g} except for the load, the sum of current vectors flowing through the two conducting lines is not zero, and thus a detection signal having a level different from the reference value determined when the leakage current is zero may be outputted. Here, the level of the leakage current may be determined by other resistance R_{g} causing the leakage current, and the HCT 21 may have the same output characteristic according to the level of the leakage current as that of FIG. 2C.

Referring again to FIG. 1, the leakage current determining unit 23 may determine the cause of the leakage current according to the rate of hourly change in the level of the leakage current detected in the leakage current detecting unit 21. Also, the leakage current determining unit 23 may output a trip signal for tripping connection of the DC power unit 11 and an alarm signal for warning the risk so as to safety at an appropriate time according to the determined cause and level of the leakage current. The trip signal outputted from the leakage current detecting unit 21 may be provided to a separate circuit breaker to operate. Also, the alarm signal outputted from the leakage current detecting unit 21 may be provided to a separate warning unit (for example, a warning screen or a siren) to allow a user or manager to recognize the risk of the leakage current.

Hereinafter, a method for detecting the leakage current according to an embodiment of the present invention will be described in detail. The method for detecting the leakage current will be described together with the effect of the leakage current detecting apparatus having the above-described components according to an embodiment of the present invention.

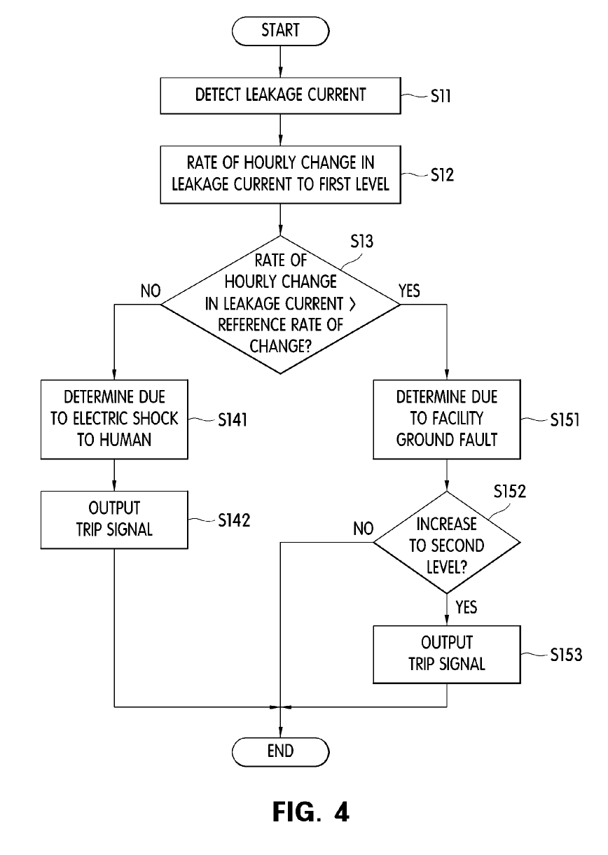

FIG. 4 is a flowchart showing a method of detecting leakage current according to an embodiment of the present invention.

Referring to FIGS. 1 and 4, the method for detecting the leakage current according to an embodiment of the present invention may include a leakage current detecting process S11 in which the leakage current detecting unit 21 detects the current flow between the DC power unit 11 and the load 13 to detect whether the leakage current is generated and the level of the leakage current and leakage current determining processes S12, S13, S141, and S151 in which the leakage current determining unit 23 determines the cause of the leakage current according to the rate of hourly change in the level of the leakage current detected in the leakage current detecting process S11.

The leakage current detecting process S11 may include determining the level of the leakage current corresponding to a difference (the sum of the vectors) between the currents flowing in the first conducting line 15 through which the current flows from the DC power unit 11 to the load and in the second conducting line 17 through which the current flows from the load to the ground. As described above, the leakage current detecting unit 21 may be provided with the HCT. The HCT may be disposed to surround a conducting line part including the first and second conducting lines 15 and 17 to detect a level of the magnetic field corresponding to the sum of level of the magnetic field generated by the current flowing through the first conducting line 15 and level of the magnetic field generated by the current flowing through the second conducting line 17 in a direction opposite to that of the current flowing through the first conducting line 15, thereby outputting a voltage value corresponding to the level of the leakage current.

Then, the leakage current determining processes S12, S13, S141, and S151 may be performed by the leakage current determining unit 23.

The leakage current determining processes may include the processes S12, S13, S141, and S151 for detecting the rate of hourly change in the level of the leakage current detected in the leakage current detecting process to determine the cause of the leakage current. The leakage current may be distinguished into a leakage current generated by an electric shock to a human and a leakage current generated by a facility ground fault of an electrical/electronic device itself

Inventors of the present invention have found that an amount of leakage current due to the electric shock to the human is different from an amount of leakage current due to the facility ground fault through the experiment and developed the apparatus and method for detecting the leakage current capable of distinguishing the cause of the leakage current into a case due to the electric shock to the human and a case due to the facility ground fault.

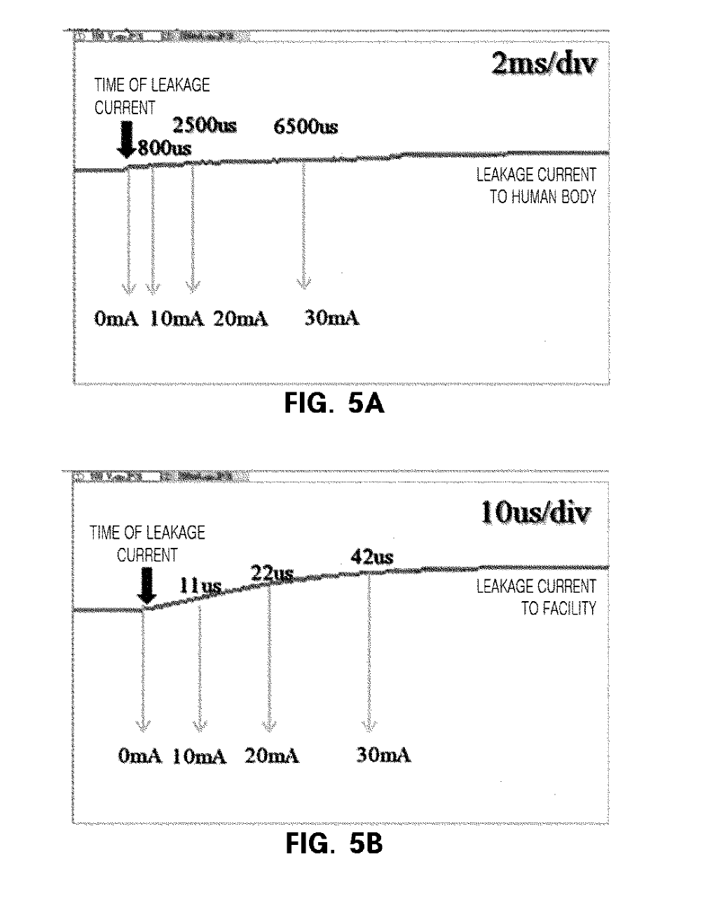

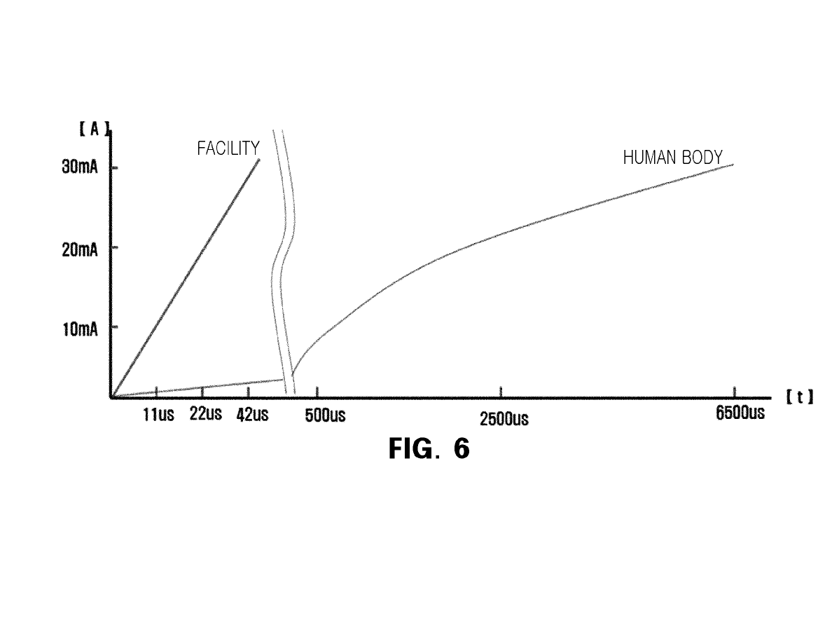

FIG. 5A is a graph showing characteristics of the leakage current due to an electric shock to a human body, and FIG. 5B is a graph showing characteristics of the leakage current due to a facility ground fault, and FIG. 6 is a graph comparing a leakage current pattern due to the electric shock with a leakage current pattern due to the ground fault.

As illustrated in FIGS. 5A, 5B, and 6, upon comparison of the two leakage current patterns, it can be seen that although the leakage current generated due to the facility ground fault rapidly increases, the leakage current generated due to the electric shock to the human increases very slowly when compared to the leakage current generated due to the facility ground fault. While the leakage current due to the electric shock to the human of FIG. 5A takes approximately 2.5 ms until the leakage current increases to about 20 mA, the leakage current due to the facility ground fault of FIG. 5B takes approximately 0.022 ms until the leakage current increases to about 20 mA. In consideration of this characteristic, through program processing of a microprocessor that is included in the leakage current determining unit 23 to perform various calculations, the rate of change of the leakage current per hour, that is, a slope may be analyzed to distinguish the causes of the leakage current, either the case due to the electric shock to the human or the case due to the facility ground fault.

In particular, since the leakage current due to the electric shock may deadly affect the human body when the leakage current increases more than about 30 mA, in an embodiment of the present invention, when the leakage current is generated less than about 30 mA (for example, about 10 mA or about 20 mA), a rate of change in the leakage current per hour at that time may be detected to determine the cause of the leakage current.

That is, the leakage current determining process may include a process S141 in which the leakage current determining unit 23 detects (a process S12) a rate of hourly change in the leakage current until the level of the leakage current in the leakage current detecting process increases from a time at which the leakage current is generated to a predetermined first level (a level of the leakage current which does not affect to the human body, for example, about 20 mA), and in a case S13 in which the rate of hourly change in the leakage current to the first level is less than a predetermined reference rate of change, the cause of the leakage current is determined as the electric shock to the human. In this case, in the leakage current determining process, the leakage current determining unit 23 may output the trip signal to the circuit breaker 25 immediately after the determination to trip the power supplied by the DC power unit 11 so as to protect life and output an alarm signal to a warning unit 27, thereby allowing the user to recognize the occurrence of the leakage current due to the electric shock to the human.

The leakage current determining process may include a process S151 in which the leakage current determining unit 23 detects (a process S12) a rate of hourly change in the leakage current until the level of the leakage current in the leakage current detecting process increases from a time at which the leakage current is generated to a predetermined first level (a level of the leakage current which does not affect to the human body, for example, about 20 mA), and in a case S13 in which the rate of hourly change in the leakage current to the first level is higher than a predetermined reference rate of change, the cause of the leakage current is determined as the facility ground fault.

If the leakage current is generated due to the facility ground fault, when the level of the leakage current is about 300 mA, it may adversely affect the facility. Thus, if the cause of the leakage current is determined as the facility ground fault through the rate of hourly change to the first level of about 20 mA, when the level is at a second level (for example, about 200 mA) that is just before the level of the leakage current increases to a level that may adversely affect the facility, the supply of the DC power may be tripped. That is, when the leakage current determining unit 23 determines the cause of the leakage current as the facility ground fault in the leakage current determining process, it is determined (S152) whether the level of the leakage current increases to a predetermined second level. When the level of the leakage current increases to the second level, the trip signal for tripping the power provided from the DC power unit may be outputted to the circuit breaker 25, and the alarm signal may be outputted to the warning unit 27 so that the users may recognize the occurrence of the leakage current due to the facility ground fault.

Hereinafter, operation characteristic according to the apparatus and method for detecting the leakage current according to an embodiment of the present invention will be described in detail.

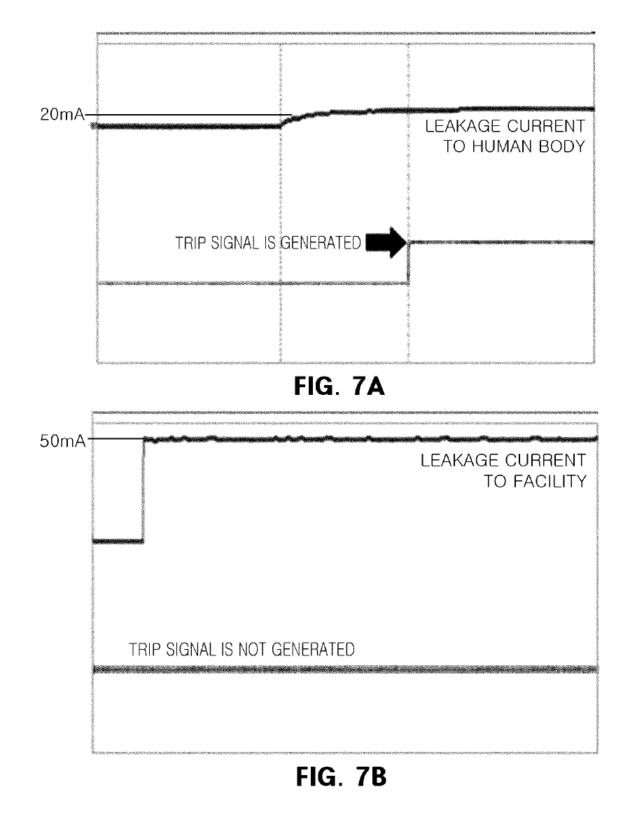

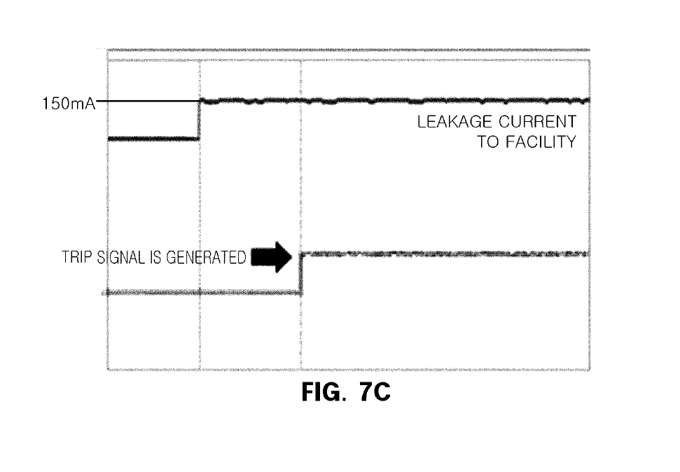

FIG. 7A is a graph of experimental results showing operation characteristics when a human body receives a shock by the leakage current of 30 mA which is over the first level of human limiting value of 20 mA, in the apparatus and method for detecting a leakage current according to an embodiment of the present invention, and FIG. 7B is a graph of experimental results showing an example of operation characteristics when a facility ground fault occurs by the leakage current of 50 mA which is bellow the second level of facility limiting value of 150 mA, in the apparatus and method for detecting a leakage current according to an embodiment of the present invention, and FIG. 7C is a graph of experimental results showing another example of operation characteristics when the facility ground fault occurs by the leakage current of around 155 mA which is over the second level of facility limiting value of 150 mA, in the apparatus and method for detecting a leakage current according to an embodiment of the present invention.

The apparatus and method for detecting the leakage current according to an embodiment of the present invention may perform information processing with respect to a waveform generated from the leakage current by filtering to generate a trip signal such as a trip signal to which a delay time and filtering operation are applied.

That is, as illustrated in FIG. 7A, when the leakage current (upper line) slowly increases to the first level, and the cause of the leakage current is determined as the electric shock to the human, the apparatus and method for detecting the leakage current according to an embodiment of the present invention generate the trip signal at a low level that is less than the level that may adversely affect the human body. Here, the trip signal (lower line) may be generated when after a predetermined time elapses after the leakage current reaches the first level, or when the leakage level reaches an extent that the level (for example, less than about 20 mA or about 30 mA) of the leakage current does not adversely affect the human body, which is higher than the first level.

As illustrated in FIG. 7B, when the leakage current (upper line) rapidly increases to the first level, and the cause of the leakage current is determined as the facility ground fault, the apparatus and method for detecting the leakage current according to an embodiment of the present invention continuously detect the level without generating the trip signal (lower line) until the level of the leakage current reaches the second level, that is a level that is less than a level that may adversely affect the facility. Here, between the first level and the second level, for example, at about 50 mA, the power is not tripped. Thus, unnecessary tirp due to the noise may be prevented.

As illustrated in FIG. 7C, the apparatus and method for detecting the leakage current according to an embodiment of the present invention determine the cause of the leakage current as the facility ground fault and generate the trip signal at a high level that is less than the level that may adversely affect the facility when it is determined that the level of the leakage current (upper line) reaches the second level. Here, the trip signal (lower line) may be generated when after a predetermined time elapses after the leakage current reaches the second level, or when the leakage level reaches an extent of the level (for example, between 200 mA and about 300 mA), which is higher than the second level.

As described above, according to the present invention, unlike an existing leakage current detecting method in which power is tirpped when a single level of leakage current is detected, the cause of a leakage current may be distinguished to be due to an electric shock to a human or due to a facility ground fault, based on an increase in amount (an increasing amount per hour, i.e., the slope) of the leakage current. In the case of an electric shock to a human, the power may be tripped when the level of the leakage current is low, and an alarm may be issued. In the case of a facility ground fault, the power may be tripped and an alarm may be issued only when a sufficiently large leakage current that may adversely influence the facility is generated. Thus, according to the present invention, the inefficiency of electric power management that trips power even for relatively small currents such as noise may be improved upon, and responses may be more effectively made to electric shocks to humans which are life-threatening. That is, the present invention may achieve two objectives—the first being that a leakage current detecting device may operate with reduced sensitivity for current such as noise so as to promote stability in the supply of power to a main facility, and the second being that the leakage current detecting device may simultaneously operate with high sensitivity for electric shocks to humans and thus save lives. Also, according to the present invention, the leakage current detecting device may be applied to an electricity distribution network that requires high reliability, and integrated protection from electric shocks to humans and fire-related accidents caused by leakage current in a facility are possible in the TN grounding manner of a DC distribution system.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An apparatus for detecting leakage current in a DC distribution system of a TN grounding manner, the apparatus comprising:
a leakage current detecting unit configured to detect a current flow between a DC power unit and a load to detect whether the leakage current is generated and a level of the leakage current; and
a leakage current determining unit configured to determine that the cause of the leakage current is either an electric shock to a human or a facility ground fault according to a rate of hourly change in the level of the leakage current detected in the leakage current detecting unit.

2. The apparatus of claim 1, wherein the leakage current detecting unit detects a level of the leakage current corresponding to a difference between current flowing in a first conducting line through which current flows from the DC power unit to the load and current flowing in a second conducting line through which current flows from the load to a ground.

3. The apparatus of claim 2, wherein the leakage current detecting unit comprises a hall effect sensor current transformer (HCT) disposed to surround a conducting line part comprising the first and second conducting lines to detect a level of a magnetic field corresponding to the sum of level of the magnetic field generated by the current that flows through the first conducting line and level of the magnetic field generated by the current, which flows in a direction opposite to that of the current flowing through the first conducting line, through the second conducting line, thereby outputting a voltage value corresponding to the level of the leakage current.

4. The apparatus of claim 1, wherein the leakage current determining unit detects the rate of hourly change in the level of the leakage current detected by the leakage current detecting unit to determine the cause of the leakage current.

5. The apparatus of claim 4, wherein the leakage current determining unit determines the cause of the leakage current as the electric shock to the human when the rate of hourly change in the level of the leakage current detected by the leakage current detecting unit until the level of the leakage current increases from a time at which the leakage current is generated to a predetermined first level is less than a predetermined reference rate of change.

6. The apparatus of claim 5, wherein the leakage current determining unit outputs a trip signal for tripping power provided from the DC power unit immediately after determining the cause of the leakage current as the electric shock to the human.

7. The apparatus of claim 4, wherein the leakage current determining unit determines the cause of the leakage current as the facility ground fault when the rate of hourly change in the level of the leakage current detected by the leakage current detecting unit until the level of the leakage current increases from a time at which the leakage current is generated to a predetermined first level is higher than a predetermined reference rate of change.

8. The apparatus of claim 7, wherein, if the cause of the leakage current is determined as the facility ground fault, the leakage current determining unit outputs a trip signal for tripping power provided from the DC power unit when the level of the leakage current detected by the leakage current detecting unit increases to a predetermined second level that is higher than the first level.

9. A method for detecting leakage current in DC distribution system of a TN grounding manner, the method comprising:
a leakage current detecting process for detecting a current flow between a DC power unit and a load to detect whether the leakage current is generated and a level of the leakage current; and
a leakage current determining process for determining that the cause of the leakage current is either an electric shock to a human or a facility ground fault according to a rate of hourly change in the level of the leakage current detected in the leakage current detecting process.

10. The method of claim 9, wherein the leakage current detecting process comprises detecting a level of the leakage current corresponding to a difference between current flowing through a first conducting line through which current flows from the DC power unit to the load and current flowing through a second conducting line through which current flows from the load to a ground.

11. The method of claim 10, wherein the leakage current detecting process comprises detecting leakage current by using an HCT disposed to surround a conducting line part comprising the first and second conducting lines to detect a level of a magnetic field corresponding to the sum of level of the magnetic field generated by the current that flows through the first conducting line and level of the magnetic field generated by the current, which flows in a direction opposite to that of the current flowing through the first conducting line, through the second conducting line, thereby outputting a voltage value corresponding to the level of the leakage current.

12. The method of claim 9, wherein the leakage current determining process comprises detecting a rate of hourly change in the level of the leakage current detected in the leakage current detecting process to determine the cause of the leakage current.

13. The method of claim 12, wherein the leakage current determining process comprises determining the cause of the leakage current as the electric shock to the human when the rate of hourly change in the level of the leakage current detected in the leakage current detecting process until the level of the leakage current increases from a time at which the leakage current is generated to a predetermined first level is less than a predetermined reference rate of change.

14. The method of claim 13, wherein the leakage current determining process comprises outputting a trip signal for tripping power provided from the DC power unit immediately after determining the cause of the leakage current as the electric shock to the human.

15. The method of claim 12, wherein the leakage current determining process comprises determining the cause of the leakage current as the facility ground fault when the rate of hourly change in the level of the leakage current detected in the leakage current detecting process until the level of the leakage current increases from a time at which the leakage current is generated to a predetermined first level is higher than a predetermined reference rate of change.

16. The method of claim 15, wherein, if the cause of the leakage current is determined as the facility ground fault, the leakage current determining process comprises outputting a trip signal for tripping power provided from the DC power unit when the level of the leakage current detected in the leakage current detecting process increases to a predetermined second level that is higher than the first level.
